(19) United States
(12) Patent Application Publication
(10) Pub. No.: US 2025/0323607 A1
(43) Pub. Date: Oct. 16, 2025

(54) GALLIUM NITRIDE POWER AMPLIFIER PROTECTION

(71) Applicant: SKYWORKS SOLUTIONS, INC., Irvine, CA (US)

(72) Inventors: Patrick Marcus Naraine, Boca Raton, FL (US); Grant Darcy Poulin, Carp (CA)

(21) Appl. No.: 19/175,860

(22) Filed: Apr. 10, 2025

Related U.S. Application Data
(60) Provisional application No. 63/632,076, filed on Apr. 10, 2024.

(51) Int. Cl. H03F 1/52; H03F 3/24

(52) U.S. Cl. CPC H03F 1/523; H03F 3/245; H03F 2200/426; H03F 2200/451

(57) ABSTRACT

A device may include a first inductor coupled to a voltage source. A device may include a first transistor coupled to the first inductor. A device may include a controller coupled to the first transistor and configured to receive a sense voltage from the first transistor and compare the sense voltage to a threshold voltage, the controller further configured to output a gate voltage based on comparing the sense voltage to the threshold voltage.

### CROSS-REFERENCE TO RELATED APPLICATION

This application claims priority to U.S. Provisional Application No. 63/632,076 filed Apr. 10, 2024, entitled GALLIUM NITRIDE POWER AMPLIFIER PROTECTION, the disclosure of which is hereby expressly incorporated by reference herein in its respective entirety.

### BACKGROUND

Some embodiments of the present disclosure relate to power amplifiers.

High-power Gallium Nitride (GaN) power amplifiers operating at high drain voltages draw relatively high direct current (DC) currents under over-drive radio frequency (RF) conditions. Under over-drive conditions, DC currents can spike to levels which may damage GaN power amplifiers. In some cases, relatively large and/or external high-power and/or expensive components may be used to monitor DC currents and/or shut down power amplifier transistors. Such components can include high-wattage resistors and/or large metal-oxide-semiconductor field-effect transistor (MOSFET) DC switches.

### SUMMARY

Some implementations of the present disclosure relate to a power amplification system including a first inductor coupled to a voltage source; a first transistor coupled to the first inductor; and a controller coupled to the first transistor and configured to receive a sense voltage from the first transistor and compare the sense voltage to a threshold voltage, the controller further configured to output a gate voltage based on comparing the sense voltage to the threshold voltage.

The techniques described herein may relate to a power amplification system further including a second inductor coupled between the first inductor and the first transistor. In some aspects, the first inductor is coupled to a drain of the first transistor.

In some aspects, the controller is coupled to a source of the first transistor. The power amplification system may further include a resistor, wherein the resistor, a source of the first transistor, and the controller are coupled together at a node.

The power amplification system may further include a second transistor coupled to the first inductor. In some aspects, the first inductor is coupled to a drain of the second transistor.

In some aspects, the power amplification system further includes a second inductor coupled to the first inductor and the drain of the second transistor. The controller may be coupled to a gate of the second transistor, and the controller may be configured to supply a gate voltage to the second transistor.

The controller may be configured to output a signal in response to the sense voltage exceeding the threshold voltage.

In accordance with some implementations, the present disclosure relates to a wireless system including a first inductor coupled to a voltage source; a first transistor coupled to the first inductor; and a controller coupled to the first transistor and configured to receive a sense voltage from the first transistor and compare the sense voltage to a threshold voltage, the controller further configured to output a gate voltage based on comparing the sense voltage to the threshold voltage.

In some aspects, the wireless system further includes a second inductor coupled between the first inductor and the first transistor. The wireless system may further include a resistor, wherein the resistor, a source of the first transistor, and the controller are coupled together at a node.

The wireless system may further include a second transistor coupled to the first inductor. In some aspects, the wireless system may further include a second inductor coupled to the first inductor and the second transistor.

In some aspects, the controller is configured to output a signal in response to the sense voltage exceeding the threshold voltage.

Some implementations of the present disclosure relate to a circuit including a first inductor coupled to a voltage source; a first transistor coupled to the first inductor; and a controller coupled to the first transistor and configured to receive a sense voltage from the first transistor and compare the sense voltage to a threshold voltage, the controller further configured to output a gate voltage based on comparing the sense voltage to the threshold voltage.

The circuit may further include a second transistor coupled to the first inductor. In some aspects, the circuit may further include a second inductor coupled to the first inductor and the second transistor.

In some aspects, the controller may be configured to output a signal in response to the sense voltage exceeding the threshold voltage.

For purposes of summarizing the disclosure, certain aspects, advantages and novel features of the inventions have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIG. 1 depicts a system for tracking GaN power amplifier over-load in accordance with one or more examples.

FIG. 2 depicts another system for tracking High-power Gallium Nitride (GaN) power amplifier over-load in accordance with one or more examples.

FIG. 3 illustrates an example tracking circuit in accordance with one or more examples.

FIG. 4 illustrates a radio frequency (RF) module having a packaging substrate that can include a die mounted thereon and having a power amplification system.

FIG. 5 shows a block diagram of a wireless system that includes a power amplification system having one or more features as described herein.

### DESCRIPTION

The headings provided herein, if any, are for convenience only and do not necessarily affect the scope or meaning of the claimed invention.

High-power Gallium Nitride (GaN) power amplifiers operating at high drain voltages draw relatively high direct current (DC) currents under over-drive radio frequency (RF) conditions. Under over-drive conditions, DC currents can spike to levels which may damage GaN power amplifiers. In some cases, relatively large and/or external high-power and/or expensive components may be used to monitor DC currents and/or shut down power amplifier transistors. Such components can include high-wattage resistors and/or large metal-oxide-semiconductor field-effect transistor (MOSFET) DC switches.

GaN power amplifiers typically utilize protection circuits to protect the power amplifiers from damage, particularly where current becomes too high for the device (e.g., where the device overheats). For example, in overdrive conditions, a gate bias of a power amplifier can be lost. A negative voltage may be required at a gate of the power amplifier to pinch off the voltage and/or current prior to applying a positive voltage. As a power amplifier drives more RF power, the power amplifier also draws more RF current.

Examples described herein relate to circuit designs which may be used to protect a GaN power amplifier using compact and/or relatively inexpensive components which can be integrated on the GaN power amplifier die. In some examples, a circuit and/or GaN power amplifier die may comprise a relatively small GaN tracking transistor and/or epi-resistor to monitor and/or shut down a GaN power amplifier transistor when a set threshold current is exceeded. The DC currents between the GaN power amplifier transistor and the smaller tracking GaN transistor may be coupled together. In some examples, DC current monitoring may be implemented using a technique which can have little or no impact on the RF performance of the GaN power amplifier.

Example circuits can advantageously utilize one or more GaN device acting as power detectors to feed voltage into a control circuit. If the control circuit senses current increasing too high from RF perspective, the control circuit can trigger a shutdown. In some examples, the control circuit may be configured to drive a gate voltage further negative and/or throttling the gate voltage back to a positive voltage.

FIG. 1 depicts a system 100 for tracking GaN power amplifier over-load in accordance with one or more examples. The system includes a DC supply voltage 101 directly coupled to a sense resistor 102. The sense resistor 102 may be relatively large and/or high-power as a result of being directly coupled to the supply voltage 101.

The sense resistor 102 may be coupled to a DC switch 104 (e.g., MOSFET) and/or a shut-down circuit 106. The sense resistor 102 may be configured to provide a sense voltage 112 to the shut-down circuit 106. The switch 104 may be coupled in-series with the sense resistor 102 and/or supply voltage 101. Thus, the switch 104 may be relatively large and/or high-power.

The switch 104 may be coupled to a GaN power amplifier 108, which may comprise a transistor 110. For example, the switch 104 may be coupled to a drain of the transistor 110. A source of the transistor 110 may be coupled to ground.

The shut-down circuit 106 may be configured to compare the sense voltage 112 provided by the sense resistor 102 to a threshold voltage 114. The shut-down circuit 106 may be directly coupled to a gate of the switch 104 and/or to a gate of the transistor 110. In response to the sense voltage 112 meeting or exceeding the threshold voltage 114, the shut-down circuit 106 may be configured to output an over-current flag 116 and/or to provide a shut-down signal 118 to the switch 104 to turn off the switch 104.

The gate of the transistor 110 may be coupled to an RF input source 120 and/or may be configured to receive a gate-to-source voltage 122 from the shut-down circuit 106. The transistor 110, switch 104, resistor 102, and/or supply voltage 101 may all be coupled in series with each other. As a result, the system 100 may encounter voltage drops which can reduce maximum output power and/or efficiency of the power amplifier 108.

A source of the switch 104 and/or a drain of the transistor 110 may be coupled to and/or may provide an RF output 124. The system may be configured to receive an input signal (RF in 120) and/or may be configured to provide an amplified RF signal (RF out 124).

FIG. 2 depicts another system 200 for tracking GaN power amplifier over-load in accordance with one or more examples. The system includes a DC supply voltage 201 directly coupled to a first RF choke inductor 202. The first choke inductor 202 may be configured to block higher-frequency currents while passing lower-frequency currents.

The first inductor 202 may be directly coupled to a GaN RF power amplifier 208 and/or to a second RF choke inductor 204. The second RF choke inductor 204 may be coupled between the first RF choke inductor 202 and a GaN tracking power amplifier 205 comprising a first transistor 207. For example, a source of the first transistor 207 may be coupled to the second RF choke inductor 204. A source of the first transistor 207 may be coupled to a sense resistor 209 and/or to a shut-down circuit 206. The first transistor 207 may be configured to provide a sense voltage 212 to the shut-down circuit 206.

The shut-down circuit 206 may be configured to compare the sense voltage 212 provided by the tracking power amplifier 205 to a threshold voltage 214. In response to the sense voltage 212 meeting or exceeding the threshold voltage 214, the shut-down circuit 206 may be configured to output an over-current flag 216 and/or drive down a gate-to-source voltage 218 provided by the circuit 206. In some examples, the circuit 206 may be directly coupled to the GaN RF power amplifier 208.

The GaN RF power amplifier 208 may comprise a second transistor 210. The circuit 206 may be coupled to a gate of the second transistor 210 and/or may be configured to supply the gate-to-source voltage 218 to the gate of the second transistor 210. In some examples, an RF input 220 may be coupled to the gate of the second transistor 210.

The first choke inductor 202, the second choke inductor 204, and/or a drain of the second transistor 210 may be coupled to and/or may provide an RF output 224. The system may be configured to receive an input signal (RF in 220) and/or may be configured to provide an amplified RF signal (RF out 224).

The system 200 advantageously utilizes the first choke inductor 202 and/or second choke inductor 204 to allow a relatively small percentage of DC current drawn by the power amplifier 205 (e.g., RF GaN power amplifier) to pass into the source and/or drain of the first transistor 207 (e.g., tracking transistor). The source of the first transistor 207 may be coupled to the sense resistor 209 (which may be greater than five-hundred ohms) to advantageously develop the sense voltage 212 for use by the circuit 206. If the circuit 206 determines that the sense voltage 212 exceeds the threshold voltage 214, the circuit 206 can advantageously shut down the GaN RF power amplifier 208 and/or second transistor 210 by driving the gate-to-source voltage 218 below the threshold voltage 214 (e.g., approximately less than negative five volts).

The system 200 (e.g., tracking circuit) may advantageously not require high-power sense resistors and/or MOSFET DC switches. The power amplifier 205, sense resistor 209, and/or GaN RF power amplifier 208 may be disposed on the same semiconductor die. In this way, tracking current at the system 200 may closely follow source current from the voltage source 201. Absolute value of the tracking current and/or the sense voltage 212 can be adjusted by changing resistance of the sense resistor 209.

FIG. 3 illustrates an example tracking circuit 300 in accordance with one or more examples. The circuit may comprise a supply voltage 301 coupled to a first choke inductor 302 at a first side of the first choke inductor 302. A second side of the first choke inductor 302 may be coupled to a first side of a second choke inductor 304. A second side of the second choke inductor 304 may be coupled to a drain of a first transistor 307, which may comprise a GaN tracking transistor. A gate of the first transistor 307 may be coupled to a third inductor and/or a source of the first transistor 307 may be coupled to a sense resistor 309 and/or to ground. The second side of the first choke inductor 302 may be coupled to a source and/or drain of a second transistor 310, which may comprise an RF GaN transistor.

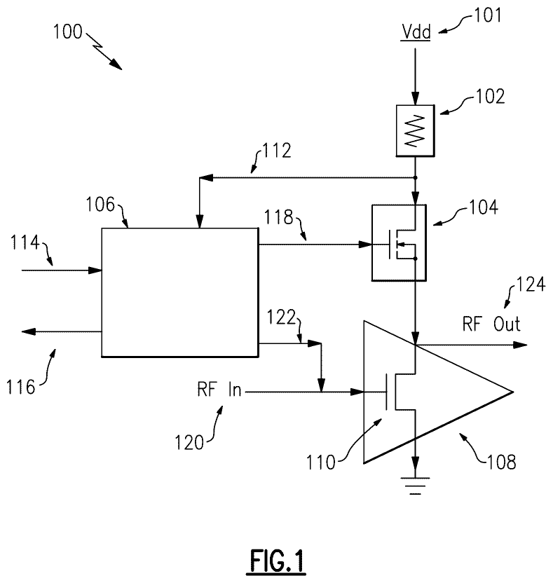

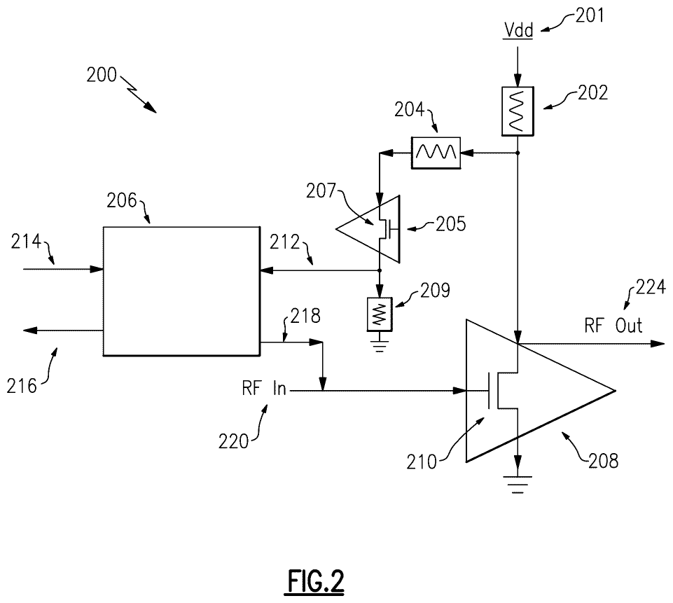

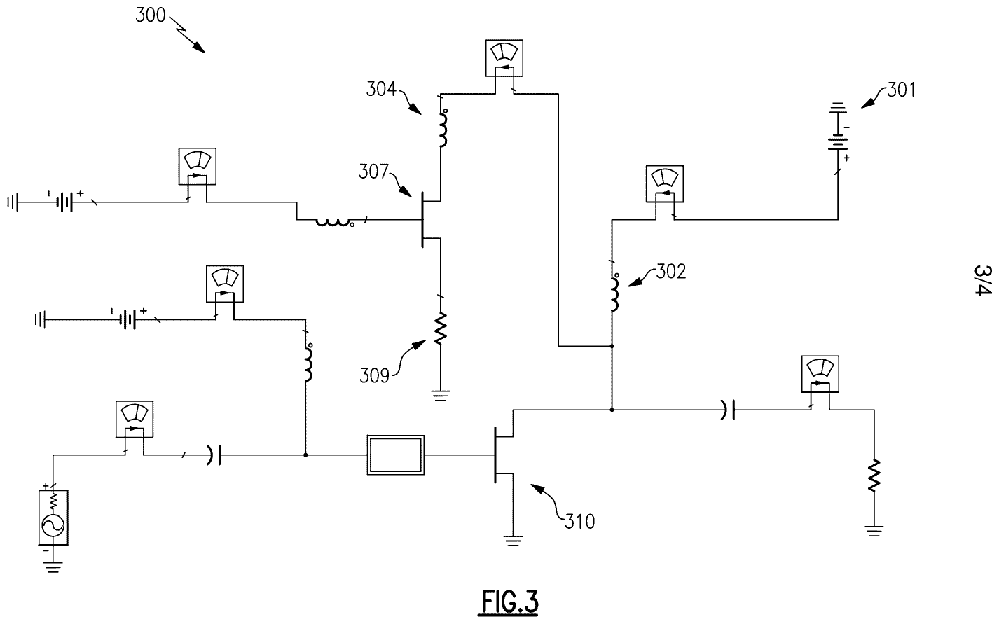

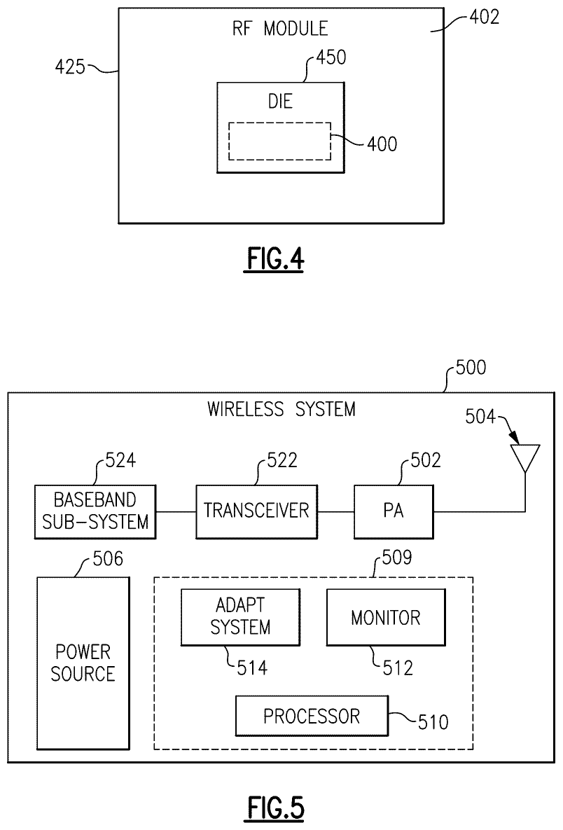

FIG. 4 shows that in some embodiments, an RF module 425 having a packaging substrate 402 can include die 450 mounted thereon and having a power amplification system 400. Such a power amplification system can include a power amplifier and a monitor and adapt system having one or more features as described herein.

FIG. 5 shows a block diagram of a wireless system 500 that includes a power amplification system having one or more features as described herein. The power amplification system can include a power amplifier 502, and such a power amplifier can be in communication with a transceiver 522, and receive from the transceiver 522 an RF signal to be amplified and transmitted through an antenna 504. The transceiver 522 can be in communication with a baseband sub-system 524 that is configured to process digital signals. In some embodiments, the baseband sub-system 524 can include at least a portion of a DPD system having one or more features as described herein, and such a DPD system can be a part of the power amplification system.

In the example of FIG. 5, a monitor and adapt system 509 having one or more features as described herein can be a part of the foregoing power amplification system. The monitor and adapt system 509 can include a monitor system 512 and an adapt system 514. In some embodiments, the monitor and adapt system 509 can also include a processor 510 configured to support either or both of the monitor system 512 and the adapt system 514.

In the example of FIG. 5, the wireless system 500 is shown to further include a power source 506 configured to power some or all of the various parts of the wireless system 500.

The present disclosure describes various features, no single one of which is solely responsible for the benefits described herein. It will be understood that various features described herein may be combined, modified, or omitted, as would be apparent to one of ordinary skill. Other combinations and sub-combinations than those specifically described herein will be apparent to one of ordinary skill, and are intended to form a part of this disclosure. Various methods are described herein in connection with various flowchart steps and/or phases. It will be understood that in many cases, certain steps and/or phases may be combined together such that multiple steps and/or phases shown in the flowcharts can be performed as a single step and/or phase. Also, certain steps and/or phases can be broken into additional sub-components to be performed separately. In some instances, the order of the steps and/or phases can be rearranged and certain steps and/or phases may be omitted entirely. Also, the methods described herein are to be understood to be open-ended, such that additional steps and/or phases to those shown and described herein can also be performed.

Some aspects of the systems and methods described herein can advantageously be implemented using, for example, computer software, hardware, firmware, or any combination of computer software, hardware, and firmware. Computer software can comprise computer executable code stored in a computer readable medium (e.g., non-transitory computer readable medium) that, when executed, performs the functions described herein. In some embodiments, computer-executable code is executed by one or more general purpose computer processors. A skilled artisan will appreciate, in light of this disclosure, that any feature or function that can be implemented using software to be executed on a general-purpose computer can also be implemented using a different combination of hardware, software, or firmware. For example, such a module can be implemented completely in hardware using a combination of integrated circuits. Alternatively or additionally, such a feature or function can be implemented completely or partially using specialized computers designed to perform the particular functions described herein rather than by general purpose computers.

Multiple distributed computing devices can be substituted for any one computing device described herein. In such distributed embodiments, the functions of the one computing device are distributed (e.g., over a network) such that some functions are performed on each of the distributed computing devices.

Some embodiments may be described with reference to equations, algorithms, and/or flowchart illustrations. These methods may be implemented using computer program instructions executable on one or more computers. These methods may also be implemented as computer program products either separately, or as a component of an apparatus or system. In this regard, each equation, algorithm, block, or step of a flowchart, and combinations thereof, may be implemented by hardware, firmware, and/or software including one or more computer program instructions embodied in computer-readable program code logic. As will be appreciated, any such computer program instructions may be loaded onto one or more computers, including without limitation a general-purpose computer or special purpose computer, or other programmable processing apparatus to produce a machine, such that the computer program instructions which execute on the computer(s) or other programmable processing device(s) implement the functions specified in the equations, algorithms, and/or flowcharts. It will also be understood that each equation, algorithm, and/or block in flowchart illustrations, and combinations thereof, may be implemented by special purpose hardware-based computer systems which perform the specified functions or steps, or combinations of special purpose hardware and computer-readable program code logic means.

Furthermore, computer program instructions, such as embodied in computer-readable program code logic, may also be stored in a computer readable memory (e.g., a non-transitory computer readable medium) that can direct one or more computers or other programmable processing devices to function in a particular manner, such that the instructions stored in the computer-readable memory implement the function(s) specified in the block(s) of the flowchart(s). The computer program instructions may also be loaded onto one or more computers or other programmable computing devices to cause a series of operational steps to be performed on the one or more computers or other programmable computing devices to produce a computer-implemented process such that the instructions which execute on the computer or other programmable processing apparatus provide steps for implementing the functions specified in the equation(s), algorithm(s), and/or block(s) of the flowchart(s).

Some or all of the methods and tasks described herein may be performed and fully automated by a computer system. The computer system may, in some cases, include multiple distinct computers or computing devices (e.g., physical servers, workstations, storage arrays, etc.) that communicate and interoperate over a network to perform the described functions. Each such computing device typically includes a processor (or multiple processors) that executes program instructions or modules stored in a memory or other non-transitory computer-readable storage medium or device. The various functions disclosed herein may be embodied in such program instructions, although some or all of the disclosed functions may alternatively be implemented in application-specific circuitry (e.g., ASICs or FPGAs) of the computer system. Where the computer system includes multiple computing devices, these devices may, but need not, be co-located. The results of the disclosed methods and tasks may be persistently stored by transforming physical storage devices, such as solid-state memory chips and/or magnetic disks, into a different state.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number, respectively. The word “or” in reference to a list of two or more items, that word covers all of the following interpretations of the word: any of the items in the list, all of the items in the list, and any combination of the items in the list. The word “exemplary” is used exclusively herein to mean “serving as an example, instance, or illustration.” Any implementation described herein as “exemplary” is not necessarily to be construed as preferred or advantageous over other implementations.

The disclosure is not intended to be limited to the implementations shown herein. Various modifications to the implementations described in this disclosure may be readily apparent to those skilled in the art, and the generic principles defined herein may be applied to other implementations without departing from the spirit or scope of this disclosure. The teachings of the invention provided herein can be applied to other methods and systems, and are not limited to the methods and systems described above, and elements and acts of the various embodiments described above can be combined to provide further embodiments. Accordingly, the novel methods and systems described herein may be embodied in a variety of other forms; furthermore, various omissions, substitutions, and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A power amplification system comprising:
a first inductor coupled to a voltage source;
a first transistor coupled to the first inductor; and
a controller coupled to the first transistor and configured to receive a sense voltage from the first transistor and compare the sense voltage to a threshold voltage, the controller further configured to output a gate voltage based on comparing the sense voltage to the threshold voltage.

2. The power amplification system of claim 1 further comprising a second inductor coupled between the first inductor and the first transistor.

3. The power amplification system of claim 1 wherein the first inductor is coupled to a drain of the first transistor.

4. The power amplification system of claim 3 wherein the controller is coupled to a source of the first transistor.

5. The power amplification system of claim 1 further comprising a resistor, wherein the resistor, a source of the first transistor, and the controller are coupled together at a node.

6. The power amplification system of claim 1 further comprising a second transistor coupled to the first inductor.

7. The power amplification system of claim 6 wherein the first inductor is coupled to a drain of the second transistor.

8. The power amplification system of claim 7 further comprising a second inductor coupled to the first inductor and the drain of the second transistor.

9. The power amplification system of claim 6 wherein the controller is coupled to a gate of the second transistor, and wherein the controller is configured to supply a gate voltage to the second transistor.

10. The power amplification system of claim 1 wherein the controller is configured to output a signal in response to the sense voltage exceeding the threshold voltage.

11. A wireless system comprising:
a first inductor coupled to a voltage source;
a first transistor coupled to the first inductor; and
a controller coupled to the first transistor and configured to receive a sense voltage from the first transistor and compare the sense voltage to a threshold voltage, the controller further configured to output a gate voltage based on comparing the sense voltage to the threshold voltage.

12. The wireless system of claim 11 further comprising a second inductor coupled between the first inductor and the first transistor.

13. The wireless system of claim 11 further comprising a resistor, wherein the resistor, a source of the first transistor, and the controller are coupled together at a node.

14. The wireless system of claim 11 further comprising a second transistor coupled to the first inductor.

15. The wireless system of claim 14 further comprising a second inductor coupled to the first inductor and the second transistor.

16. The wireless system of claim 11 wherein the controller is configured to output a signal in response to the sense voltage exceeding the threshold voltage.

17. A circuit comprising:
a first inductor coupled to a voltage source;
a first transistor coupled to the first inductor; and
a controller coupled to the first transistor and configured to receive a sense voltage from the first transistor and compare the sense voltage to a threshold voltage, the controller further configured to output a gate voltage based on comparing the sense voltage to the threshold voltage.

18. The circuit of claim 17 further comprising a second transistor coupled to the first inductor.

19. The circuit of claim 18 further comprising a second inductor coupled to the first inductor and the second transistor.

20. The circuit of claim 17 wherein the controller is configured to output a signal in response to the sense voltage exceeding the threshold voltage.
